(19) United States
(12) Patent Application Publication
(10) Pub. No.: US 2010/0061788 A1
(43) Pub. Date: Mar. 11, 2010

(54) PRINTER

(75) Inventor: Kiyotaka Nihashi, Shizuoka-ken (JP)

Correspondence Address: TUROCY & WATSON, LLP, 127 Public Square, 57th Floor, Key Tower, CLEVELAND, OH, 44114, US

(73) Assignee: TOSHIBA TEC KABUSHIKI KAISHA, Tokyo (JP)

(21) Appl. No.: 12/553,397

(22) Filed: Sep. 3, 2009

(30) Foreign Application Priority Data
Sep. 9, 2008 (JP) 2008-231284

(51) Int. Cl. B41J 2/235; H05K 7/20

(52) U.S. Cl. 400/124.13; 361/709

(57) ABSTRACT

A printer is provided with lugs protruding individually from opposite end portions of a heat sink on the upper end side thereof and collar portions disposed individually on axially opposite end portions of a platen roller and configured to contact the lugs of the heat sink, thereby moving the heat sink away from the platen roller against an urging force of a spring, while a pivotable cover is being pivoted to be opened or closed.

### CROSS-REFERENCE TO RELATED APPLICATION

This application is based upon and claims the benefit of priority from prior Japanese Patent Application No. 2008-231284, filed Sep. 9, 2008, the entire contents of which are incorporated herein by reference.

### TECHNICAL FIELD

The present invention relates to a clamshell printer, and more specifically, to structures of a platen roller and heat sink.

### BACKGROUND

A printer of this type is provided with a main body that can be opened and closed by pivoting a pivotable cover. A printing section is disposed in the main body. The pivotable cover is provided with a platen roller for supporting paper. The printing section includes a heat sink and thermal head attached thereto. The heat sink has its proximal end side pivotably supported by a pivot and its distal end side (opposite from the proximal end side) urged to pivot toward the platen roller by a spring member.

The pivotable cover is opened and closed to facilitate replacement of paper or internal inspection of the printer. The platen roller is configured to reach a printing position when the cover is closed. When this is done, the thermal head of the heat sink is pressed against the platen roller via the paper to be ready for printing, by the urging force of the spring member. At this time, moreover, the platen roller is held under pressure by the distal end side of the heat sink that is urged by the spring member, whereby the pivotable cover is locked (e.g., U.S. Pat. No. 5,579,043).

Conventionally, however, the distal end side of the heat sink is located in a trajectory of the platen roller while the pivotable cover is being pivoted to be opened or closed. While the cover is being pivoted, therefore, the platen roller is in contact with the distal end side of the heat sink.

Accordingly, the paper is rubbed on the distal end side of the heat sink by the platen roller while the pivotable cover is being pivoted. If the paper is a thick one or thermosensitive paper with high color developing sensitivity, in particular, flaws or impressions may be produced or remain on it.

Further, the rubbed paper produces paper dust, which inevitably adheres to the thermal head, thus resulting in obscure printing.

Since the distal end side of the heat sink is in sliding contact with the platen roller while the pivotable cover is being pivoted to be opened or closed, moreover, the cover is unduly forced and cannot be pivoted smoothly.

### SUMMARY

The present invention has been made in consideration of these circumstances, and it is an object of the invention to provide a printer in which a pivotable cover can be smoothly pivoted to be opened or closed without impressing or damaging paper and which ensures clear printing.

A printer according to an aspect of the invention comprises a main body including a pivotable cover, a platen roller which is disposed on the inner surface side of the pivotable cover and supports a paper, a heat sink disposed in the main body so that the proximal end side thereof is pivotably supported by a pivot and that side opposite from the proximal end side is located in a trajectory of the platen roller while the pivotable cover is being pivoted, a printhead mounted on one surface side of the heat sink and opposed to the platen roller, an urging member configured to elastically urge the other surface side of the heat sink to turn the heat sink around the pivot, thereby pressing the printhead against the platen roller via the paper, lugs protruding individually from opposite end portions of the heat sink on the side opposite from the proximal end side, and collar portions disposed individually on axially opposite end portions of the platen roller and configured to contact the lugs of the heat sink, thereby moving the heat sink away from the platen roller against an urging force of the urging member, while the pivotable cover is being pivoted to be opened or closed.

A printer according to another aspect of the invention comprises a main body including a pivotable cover, a platen roller which is disposed on the inner surface side of the pivotable cover and supports a paper, a heat sink disposed in the main body so that the proximal end side thereof is pivotably supported by a pivot and that side opposite from the proximal end side is located in a trajectory of the platen roller while the pivotable cover is being pivoted, a printhead mounted on one surface side of the heat sink and opposed to the platen roller, an urging member configured to elastically urge the other surface side of the heat sink to turn the heat sink around the pivot, thereby pressing the printhead against the platen roller via the paper, and collar portions disposed individually on axially opposite end portions of the platen roller, having an outside diameter larger than that of the platen roller, and configured to contact opposite end portions of the heat sink on the side opposite from the proximal end side, thereby moving the heat sink away from the platen roller against an urging force of the urging member, while the pivotable cover is being pivoted to be opened or closed.

According to the present invention, a pivotable cover can be smoothly pivoted to be opened or closed without impressing or damaging paper, and clear printing can be performed.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a configuration view showing a clamshell printer according to an embodiment of the invention;

FIG. 2 is a front view of a printing section shown in FIG. 1;

FIG. 3 is a perspective view of the printing section of FIG. 1;

FIG. 4 is a plan view of the printing section of FIG. 1;

FIG. 5 is a view showing how a collar portion of a platen roller contacts a lug on a heat sink shown in FIG. 1;

FIG. 6 is a view showing how the heat sink of FIG. 5 is pivoted away from the platen roller;

FIG. 7 is a view showing how the platen roller of FIG. 6 reaches a printing position in which a thermal head contacts the platen roller;

FIG. 8 is a perspective view showing a printing section according to another embodiment of the invention; and

FIG. 9 is a view showing a thermal head in contact with a platen roller of FIG. 6 in its printing position.

### DETAILED DESCRIPTION

Embodiments of the present invention will now be described in detail with reference to the accompanying drawings.

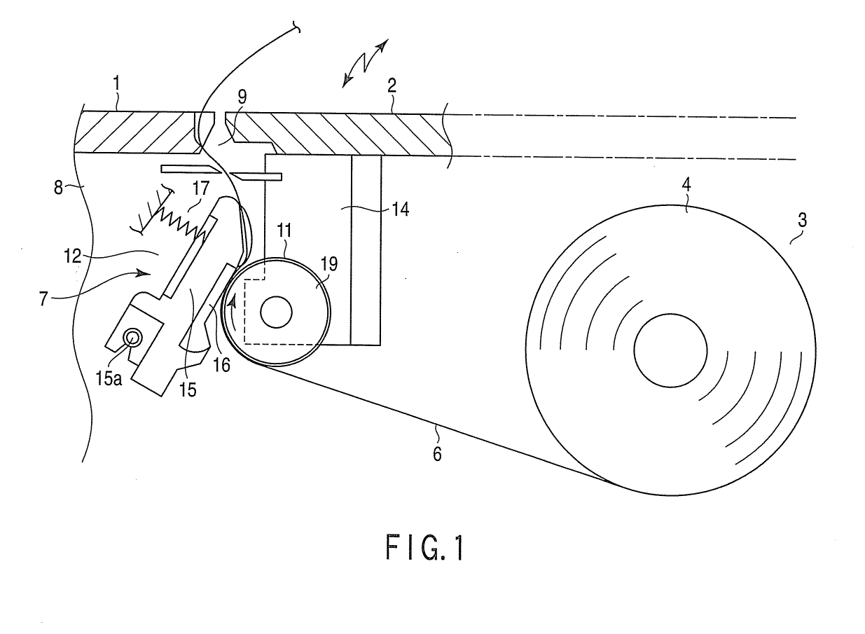

FIG. 1 is a configuration view showing a clamshell printer according to an embodiment of the invention.

In FIG. 1, number 1 denotes a main body of the printer. A top opening of the main body 1 can be opened and closed by pivoting a pivotable cover 2. The cover 2 can be vertically swung up and down around a pivot (not shown) as indicated by an arrow. A rolled-paper mounting portion 3 is disposed in the main body 1, and a roll of paper 4 is mounted in the mounting portion 3. The leading end portion of the paper 4 is drawn out of the mounting portion 3 and conveyed along a conveying path 6. A printing section 7, cutter section 8, and exit section 9 are arranged in succession in a conveying direction along the conveying path 6.

The printing section 7 is provided with a platen roller 11 and printhead portion 12, which are opposed to each other with the conveying path 6 between them. The platen roller 11 is rotatably mounted on the pivotable cover 2 by the mounting member 14 and can be rotated in the direction of an arrow by a drive mechanism (not shown).

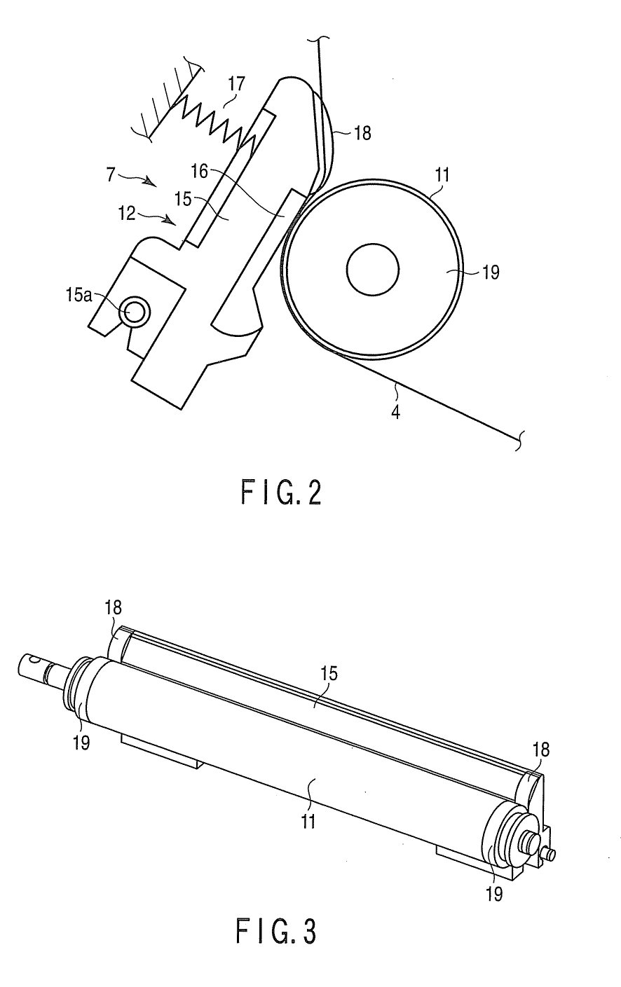

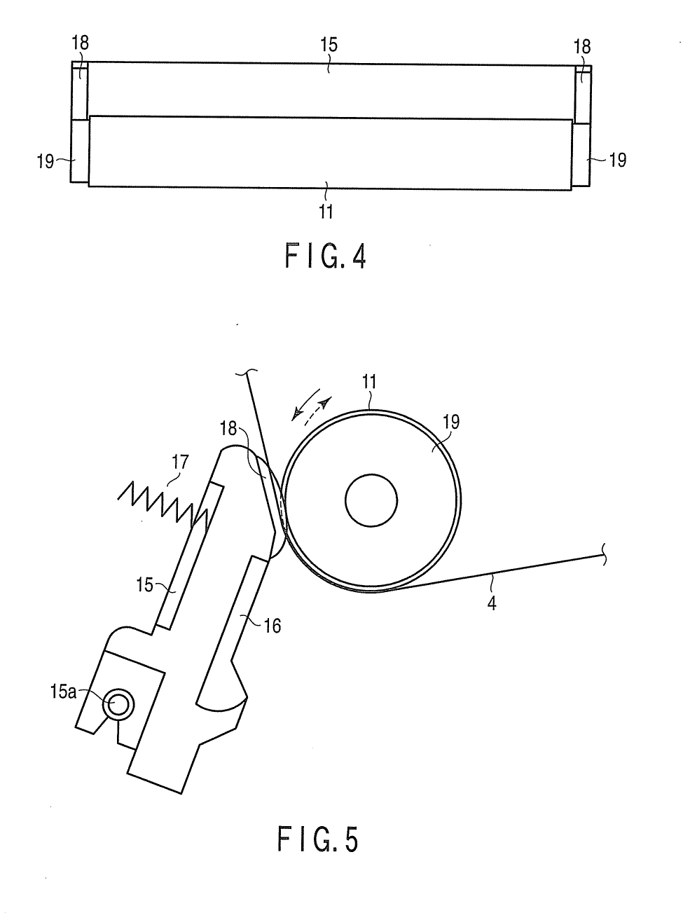

FIGS. 2 to 4 are a front view, perspective view, and plan view, respectively, of the printing section 7.

The printhead portion 12 includes a heat sink 15 and thermal head 16. The lower end side (or proximal end side) of the heat sink 15 is pivotably supported by a pivot 15a. The thermal head 16 is mounted on the front side of the heat sink 15 and serves as a printhead. The back of the heat sink 15 on its upper end side (opposite from the proximal end side) is urged toward the platen roller 11 by a spring 17 for use as an urging member, whereby the thermal head 16 is pressed against the roller 11 via the paper 4. Further, arcuate lugs 18 protrude integrally from the opposite end portions of the heat sink 15 on its upper end side.

Furthermore, collar portions 19 are disposed individually on the axially opposite end portions of the platen roller 11. The outside diameter of these collar portions 19 is a little smaller than that of the platen roller 11. The pivotable cover 2 is configured to contact the lugs 18 on the opposite end portions of the heat sink 15 while it is being pivoted to be opened or closed.

The following is a description of a printing operation.

First, as shown in FIG. 1, the pivotable cover 2 is closed so that the leading end side of the paper 4 is held between the platen roller 11 and thermal head 16. In this state, the platen roller 11 is rotated in the direction of the arrow by the drive mechanism (not shown), and the thermal head 16 is heated based on print information. As the platen roller 11 rotates, the paper 4 is conveyed between the roller 11 and thermal head 16. The information is printed on the paper 4 as the head 16 is heated. The paper 4 having the information printed thereon is discharged through the exit section 9. When the paper 4 is delivered to a predetermined length, the cutter section 8 is driven to cut it, and a user receives the cut paper.

In replacing the roll of paper 4 or internally inspecting the printer, the pivotable cover 2 is pivoted upward to be opened. After the replacement or internal inspection is finished, the cover 2 is pivoted downward to be closed. When the cover 2 is closed, the platen roller 11 reaches a printing position, whereupon the thermal head 16 is pressed against the roller 11 via the paper 4.

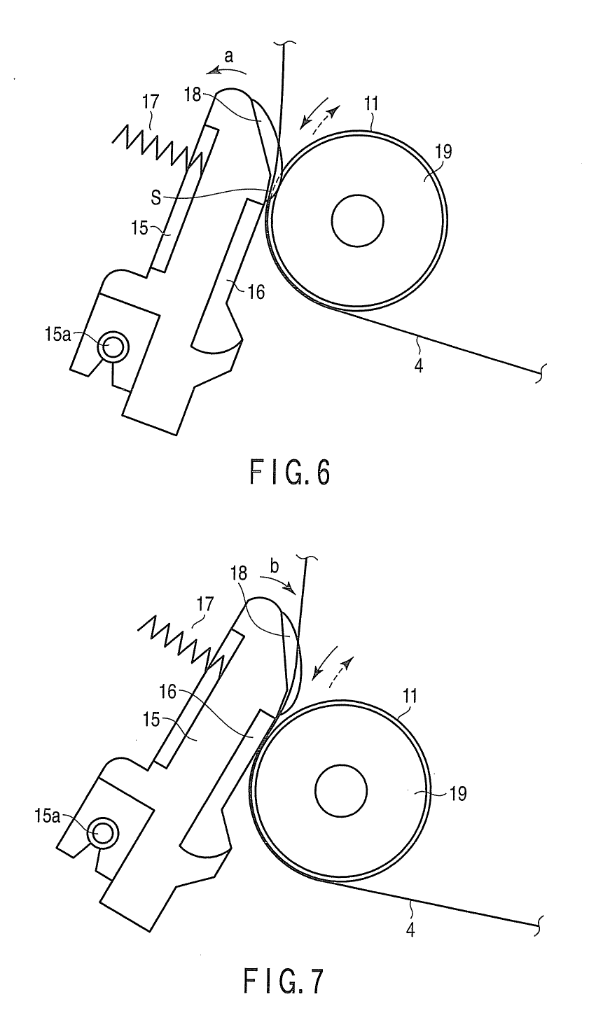

If the pivotable cover 2 is closed, the collar portions 19 on the opposite end portions of the platen roller 11 first contact their corresponding arcuate lugs 18 on the upper end side of the heat sink 15, as shown in FIG. 5. If the platen roller 11 is further moved downward from this state, as indicated by a solid arrow in FIG. 6, the lugs 18 of the heat sink 15 are pushed. Thereupon, the heat sink 15 is pivoted away from the roller 11 around the pivot 15a, as indicated by arrow a in FIG. 5, resisting the urging force of the spring (urging member) 17. When this is done, a gap S is formed between the upper end side of the heat sink 15 and the roller 11. Thus, the paper 4 is located within the gap S without being rubbed on the heat sink 15 by the platen roller 11.

If the platen roller 11 is further moved downward from the state shown in FIG. 6 to reach the printing position, as indicated by a solid arrow in FIG. 7, the collar portions 19 of the roller 11 leave the lugs 18 of the heat sink 15. Consequently, the heat sink 15 is pivoted toward the platen roller 11 by the urging force of the spring 17, as indicated by arrow b, whereupon the thermal head 16 presses the paper 4 against the roller 11 to be ready for printing.

If the pivotable cover 2 is pivoted upward to be opened, moreover, the platen roller 11 moves upward from the state shown in FIG. 7, as indicated by a broken arrow, so that the collar portions 19 contact the lugs 18 of the heat sink 15 from below, as shown in FIG. 6. Thereupon, the lugs 18 of the heat sink 15 is pushed by the platen roller 11, so that the heat sink 15 is pivoted away from the roller 11 around the pivot 15a, resisting the urging force of the spring 17. When this is done, the gap S is formed between the upper end side of the heat sink 15 and the roller 11. Thus, the paper 4 is located within the gap S without being rubbed on the heat sink 15 by the platen roller 11.

If the pivotable cover 2 is further pivoted upward, the platen roller 11 is further moved upward from the state shown in FIG. 6, as indicated by a broken arrow, to reach a standby position via the position shown in FIG. 5.

While the pivotable cover 2 is being pivoted, according to the first embodiment, as described above, the collar portions 19 on the opposite end portions of the platen roller 11 press their corresponding lugs 18 on the opposite end portions of the heat sink 15 on the upper end side thereof, so that the heat sink 15 is pivoted away from the roller 11, resisting the urging force of the spring 17. When this is done, the gap S is formed between the upper end side of the heat sink 15 and the roller 11, and the paper 4 is located within the gap S. Thus, the paper 4 cannot be rubbed on the heat sink 15, and hence, it is free from impressions even if it is made of cardboard or highly sensitive paper.

Further, clear printing can be performed without producing paper dust attributable to rubbing of the paper 4.

While the pivotable cover 2 is being pivoted, moreover, the upper end side of the heat sink 15 is not in sliding contact with the platen roller 11. Therefore, the cover 2 can be smoothly pivoted without being unduly forced.

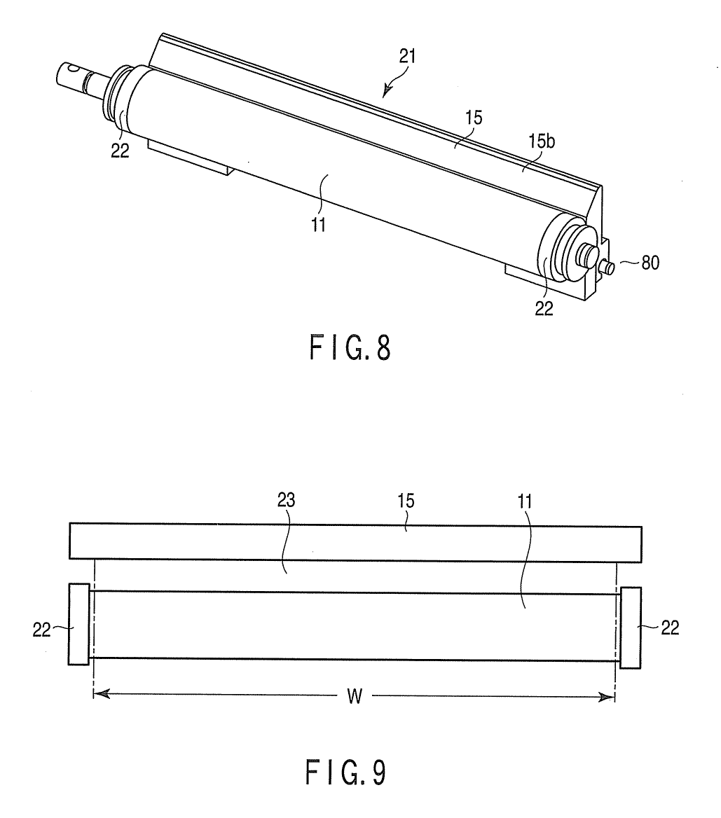

FIGS. 8 and 9 are a perspective view and plan view, respectively, of a printing section 21 of a printer according to a second embodiment of the invention.

Like numbers are used to designate like portions of the first and second embodiments and a detailed description thereof is omitted.

In the second embodiment, collar portions 22 are disposed individually on the axially opposite end portions of a platen roller 11. The outside diameter of these collar portions 22 is a little larger than that of the roller 11. Further, a width W of a thermal head 23 is smaller than the distance between the collar portions 22 on the opposite end portions of the roller 11. When the roller 11 reaches a printing position, therefore, it contacts the thermal head 23, and the collar portions 22 do not contact a heat sink 15.

In replacing a roll of paper 4 or internally inspecting the printer, a pivotable cover 2 is pivoted upward to be opened. After the replacement or internal inspection is performed in this state, the cover 2 is pivoted downward to be closed again.

When the pivotable cover 2 is closed, the platen roller 11 reaches the printing position. Thereupon, the thermal head 23 is pressed against the roller 11 via the paper 4 to be ready for printing.

If the pivotable cover 2 is closed, the collar portions 22 on the opposite end portions of the platen roller 11 first contact their corresponding opposite end portions of a slope 15b of the heat sink 15 on the top side thereof. Thereupon, the heat sink 15 is pivoted away from the roller 11 around a pivot 15a, resisting the urging force of a spring, and a gap is formed between the heat sink 15 and roller 11. The paper 4 is located within the gap without being rubbed on the heat sink 15. If the cover 2 is further pivoted downward so that the platen roller 11 reaches the printing position, the collar portions 22 of the roller 11 leave the slope 15b of the heat sink 15. Consequently, the heat sink 15 is pivoted toward the platen roller 11 by the urging force of the spring, whereupon the thermal head 23 is pressed against the roller 11 via the paper 4 to be ready for printing.

If the pivotable cover 2 is pivoted upward, on the other hand, the collar portions 22 on the opposite end portions of the platen roller 11 first contact their corresponding opposite end portions of the slope 15b of the heat sink 15 on the top side thereof from below. Thereupon, the heat sink 15 is pivoted away from the roller 11 around the pivot 15a, resisting the urging force of the spring, and the gap is formed between the heat sink 15 and roller 11. The paper 4 is located within the gap without being rubbed on the heat sink 15. If the cover 2 is further pivoted upward, the platen roller 11 is moved to its standby position.

Also in this second embodiment, as in the first embodiment described before, the paper is free from impressions even if it is made of cardboard or highly sensitive paper. Further, clear printing can be performed without producing paper dust attributable to rubbing of the paper 4. While the pivotable cover 2 is being pivoted, moreover, the distal end side of the heat sink is not in sliding contact with the platen roller. Therefore, the cover 2 can be smoothly pivoted without being unduly forced.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A printer comprising:
a main body including a pivotable cover;
a platen roller which is disposed on the inner surface side of the pivotable cover and supports a paper;
a heat sink disposed in the main body so that the proximal end side thereof is pivotably supported by a pivot and that side opposite from the proximal end side is located in a trajectory of the platen roller while the pivotable cover is being pivoted;
a printhead mounted on one surface side of the heat sink and opposed to the platen roller;
an urging member configured to elastically urge the other surface side of the heat sink to turn the heat sink around the pivot, thereby pressing the printhead against the platen roller via the paper;
lugs protruding individually from opposite end portions of the heat sink on the side opposite from the proximal end side; and
collar portions disposed individually on axially opposite end portions of the platen roller and configured to contact the lugs of the heat sink, thereby moving the heat sink away from the platen roller against an urging force of the urging member, while the pivotable cover is being pivoted to be opened or closed.

2. A printer according to claim 1, wherein the lugs of the heat sink are arcuate.

3. A printer according to claim 1, wherein the outside diameter of the collar portions is smaller than that of the platen roller.

4. A printer according to claim 1, wherein a gap is formed between the platen roller and that side of the heat sink opposite from the proximal end side as the heat sink moves away from the platen roller, and the paper is located within the gap.

5. A printer comprising:
a main body including a pivotable cover;
a platen roller which is disposed on the inner surface side of the pivotable cover and supports a paper;
a heat sink disposed in the main body so that the proximal end side thereof is pivotably supported by a pivot and that side opposite from the proximal end side is located in a trajectory of the platen roller while the pivotable cover is being pivoted;
a printhead mounted on one surface side of the heat sink and opposed to the platen roller;
an urging member configured to elastically urge the other surface side of the heat sink to turn the heat sink around the pivot, thereby pressing the printhead against the platen roller via the paper; and
collar portions disposed individually on axially opposite end portions of the platen roller, having an outside diameter larger than that of the platen roller, and configured to contact opposite end portions of the heat sink on the side opposite from the proximal end side, thereby moving the heat sink away from the platen roller against an urging force of the urging member, while the pivotable cover is being pivoted to be opened or closed.

6. A printer according to claim 5, wherein the width of the printhead is smaller than a distance between the collar portions on the axially opposite end portions of the platen roller.

7. A printer according to claim 5, wherein a gap is formed between the platen roller and that side of the heat sink opposite from the proximal end side as the heat sink moves away from the platen roller, and the paper is located within the gap.
